(19) United States
(12) Patent Application Publication
(10) Pub. No.: US 2004/0096664 A1
(43) Pub. Date: May 20, 2004

(54) Optically active polythiophene aggregate and its preparation

(76) Inventors: Michiya Fujiki, Ikoma-shi (JP); Charles E. McKenna, Pacific Palisades, CA (US); Zhong-Biao Zhang, Alhambra, CA (US)

Correspondence Address: WENDEROTH, LIND & PONACK, L.L.P., 2033 K STREET N. W., SUITE 800, WASHINGTON, DC, 20006-1021, US

(21) Appl. No.: 10/298,670

(22) Filed: Nov. 19, 2002

(51) Int. Cl. B32B 5/16

(52) U.S. Cl. 428/407; 428/462; 428/419

(57) ABSTRACT

The invention provides a polythiophene aggregate doped with metal ions, which has a characteristic spectrometric property in UV-vis-near IR region and is suitable for a photo-electoric material, said polythiophene being representable by the formula:

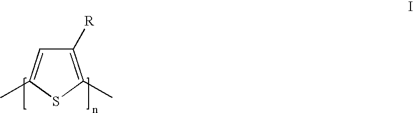

wherein R has an optically active alkyl or alkenyl group having 5 to 20 carbon atoms.

### TECHNICAL FIELD

The present invention relates to a polythiophene aggregate doped with metal ions and its preparation. Said doped aggregate is characteristic in being modified in spectrometric property in comparison with the corresponding non-doped aggregate.

### BACKGROUND ART

In the field of information and communication technology, there is an increasing demand for a recording system which can record a tremendous amount of digital information on cheap, light and tiny storage media with high speed. Optical recording systems as presently known are magneto-optical recording (MO) system and phase drift recording (PD) system.

In the MO system, the change of the rotation angle of light (called as the optical Kerr rotation angle), i.e. the change due to the alteration of optical activity, is so small as about 0.15° before and after magneto-optical “writing”. In order to attain a good contrast/noise ratio, it is needed to magnify the change of the optical Kerr rotation angle up to 0.3° before and after magneto-optical writing by providing a reflection mirror inside the device. The MO system also needs a large scale more precise device than that of magnetic recording system for detection of such a slight change of optical Kerr rotation angle as 0.3°. The “reading” and “writing” speed of the MO system is about 30 msec, which is 3 to 5 times slower than that of the magnetic recordings system. One of the reasons therefor is that the detection head containing a beam splitter is big and heavy, and the other is that the speed of the servo track is slow. Moreover, both laser head and magnetic head are necessary, which leads to the limitation for miniaturization.

If there becomes available a thin film material which is photo-readable, photo-writable and photo-erasable and has a rotation angle change of much greater than 0.3° before and after writing, it will be possible to provide the new recording system using light only. Such recording system will allow to miniaturize the recording device and accomplish writing and reading with high speed like hard disk.

Photo-readable storage density increases with inverse proportion to the square of laser wavelength. The commercially available DVD-RAM utilizes the laser source whose wavelength is 635 nm or 650 nm. Therefore, the material which can utilize the laser source with shorter wavelength (e.g., 370-430 nm; GaN laser manufactured by Nichia Corporation, Tokushima, Japan) may contribute to provide recording media whose recording densities are several times higher than that of the DVD-RAM. In addition, if there is developed a material capable of utilizing further shorter wavelength laser (e.g., 185-215 nm), the recording media may be put into practice, whose recording density are as much as several ten times higher than the DVD-RAM.

In the field of photo-network for communication, there are used a laser source with the central wavelength of 1300 nm and 1550 nm in near infrared region, a detector for near infrared region and a photo fiber with low energy-lost window. Accordingly, a photo recording material capable of responding to external stimuli in ultraviolet (UV), visible (vis) or near infrared (near IR) region is expected to be utilized in a very large area of technology and useful as a very efficient photo storage medium.

Among n-conjugated polymers, polythiophenes are excellent in conductivity and stability and attract much attention as functional polymeric materials, which are useful as polymeric semiconductors and conductors, electro-chromic materials, electro-luminescent materials, nonlinear optical materials, etc.

Recently, it was reported that poly[N-bis-(S)-3,7-dimethyloctyl)fluorene], which is a n-conjugated polymer, has a structure of cholesteric liquid crystal and comprises an optically active group, shows large absorption in circular dichroism(CD) spectrum and exhibits circularly polarized photoluminescence and electro-luminescence (M. Oda, et. al., Advanced Materials, 2000, Vol. 12, 362-365).

In general, polythiopehens show better performance than polyfluorenes when used in combination with Indium-Tin oxide and Au electrodes. Therefore, if polythiophenes having the spectrometric properties as seen on said specific polyfluorene are provided, those will be very useful as efficient materials for optical or electric devices.

It is known that poly(3,4-dichiralalkyl-thiophene) showing a characteristic spectrum of CD can be prepared by dehydrogenation polymerization using FeCl₃ (Zhang, Z. B et. al., Macromolecules, 2002, Vol. 35, 941-944). However, this polythiophene does not have a good film-forming property. Therefore, the provision of polythiophenes showing characteristic spectra of CD and having a good film-forming property has been highly desired.

### OBJECT OF THE INVENTION

A main-object of the present invention is to provide a polymeric material responding to light stimuli in UV-vis and near IR regions zo give UV-vis and near IR absorptions as well as CD absorption.

### DETAILED DESCRIPTION OF THE INVENTION

As a result of the extensive study, it has been found that a polythiophene aggregate comprising certain specific monomeric units and doped with metal ions shows a characteristic spectrometric property and a good film-forming property and can be effectively used as a material for manufacturing an optoelectronic device. This invention is based on the above finding.

Accordingly, the present invention provides a polythiophene aggeregate doped with metal ions, said polythiophene being represented by the formula:

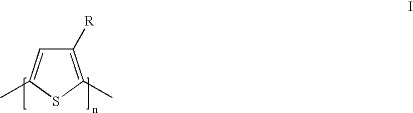

wherein R is an optically active group and n is an integer of 10 to 10,000.

The term “aggregate” is intended to mean the state of a polisher separated from its solution by adding thereto a solvent into which, the polymer is insoluble or hardly soluble. The aggregate may indicate the state of the polymer recovered as a solid material or suspended in a liquid medium.

As the optically active group represented by R, there are exemplified alkyl, alkenyl, alkynyl, alkoxy, aryl, aralkyl, etc. which may be optionally substituted with alkyl, alkoxy, halogen, nitro, amino, aryl, aralkyl or the like. Among them, particularly preferred is an alkyl or alkenyl group having 5 to 20 carbon atoms, preferably 5 to 10 carbon atoms. Specific examples of the optially active alkyl and alkenyl groups are (S) or (R)-2-methylbutyl, (S) or (R)-3-methylpentyl, (S) or (R)-3,7-dimethyloctyl, (S) or (R)-citronellyl, etc. Depending on the kind of the optically active alkyl and alkenyl groups, the spectrometric property, electric conductivity, film-forming property, etc. of the doped aggregate varies. Also, the number of the carbon atoms of the optically active alkyl or alkenyl group affords an influence on the solubility of the polymer in an organic solvent, and any appropriate one may be chosen depending on the kind of the organic solvent as used. The optically active alkyl and alkenyl groups are desired to be-neither racemized nor rearranged during the monomer synthesis or polymerization. In this respect, the one having an asymmetric carbon atom at the beta-position to the ring carbon atom of the thiophene ring can be preferably employed.

n is an integer of 10 to 10,000, preferably of 10 to 5000, more preferably of 20 to 1000, most preferably of 50 to 1000.

The molecular weight of the polythiophene is not limited but may be appropriately adjusted depending on the strength, the film-forming property, etc. of the polythiophene aggregate as desired. The weight-average molecular weight (M_{w}) of the polythiophene is about 1,000 to 5,000,000, preferably about 5,000 to 1,000,000. Further, M_{w}/Mₙ (Mₙ: number-average molecular weight) is from 1.01 to 10, preferably from 1.01 to 5.

Of the doped aggregate according to the present invention, preferred is the one of the formula I wherein R is (S) or (R)-2-methylbutyl, (S) or (R)-3-methylpentyl, (S) or (R)-3,7-dimethyloctyl or (S) or (R)-citronellyl and n is above defined, the molecular weight of the polythiophene being as above defined.

The polythiophene may be produced by a conventional procedure, for instance, by oxidation polymerization of 3-R-thiophene (wherein R is as defined above) using a polymerization catalyst such as an iron compound (e.g., iron(III) chloride, iron(III) bromide) in an inert organic solvent (e.g., hexane, isooctane, toluene, tetrahydrofuran (THF), chloroform, dimethylformamide (DMF)).

The 3-R-thiophene thiophene is obtainable by reacting 3-halothiophene (e.g., 3-bromothiophene) with an alkyl magnesium halide in the presence of a nickel compound (e.g., [1,2-bis(diphenylphosphino)propane]dichloronickel (II), [1,2-bis(diphenylphsphino)ethane]dichloronickel(II)) in an inert organic solvent (e.g., ether).

The polythiophene aggregate doped with metal ions can be prepared by treating the polythiophene with metal ions chosen from alkali metal ions (e.g., lithium ions, sodium ions, potassium ions), alkaline earth metal ions (e.g., calcium ions, magnesium ions), transition metal ions (e.g., silver ions, zinc ions, copper ions, iron ions, cobalt ions, nickel ions), rare earth metal ions (e.g., europium ions), and the like.

The treatment may be carried out by dissolving the polythiophene into a good solvent; adding a metal salt to the resultant solution; and adding a poor solvent thereto to form the polythiophene aggregate doped with metal ions. The treatment may be also carried out by dissolving the polythiophene into a good solvent; adding a poor solvent to the resulting solution; and adding a metal salt thereto to form the polythiophene aggregate doped with metal ions.

The good solvent as stated above is an organic solvent into which the polythiophene is soluble, and its examples include hexane, isooctane, toluene, benzene, THF, chloroform, DMF, etc., preferably chloroform and THF. The poor solvent is an organic solvent into which the polythiophene is insoluble or hardly soluble, and its examples include DMF, 1-octanol, methanol, ethanol, isopropanol, etc., preferably 1-octanol and methanol.

On preparation of the doped aggregate, a solution of the polythiophene to be prepared first may have a concentration of 1×10⁻⁴M to 1×10⁻²M, preferably of 5×10⁻³M to 2×10⁻²M. For formation of the polythiophene aggregate doped or not with metal ions, a poor solvent is then added to the polythiophene solution, preferably quickly at once. While no exact limitation is present on the amount of the poor solvent to be added, it is usually desirable to be greatly excessive. For example, the volume ratio of the polythiophene solution: the poor solvent may be about 1:9.

Doping of the polythiophene with metal ions may be carried out by the use of one or more kinds of metal salts before or after addition of the poor solvent to the polythiophene solution. No exact limitation is present on the kind of the metal salts as well as the counter ions of the metal salts, but it is preferred that the metal salts are soluble in the solvents as employed on formation of the polythiophene aggregate.

The amount of the metal salt to be employed may be decided on the amount of the metal ion desired to dope into the polythiophene aggregate. The molar ratio of the metal salt to the repeating unit of the polythiophene may be from 0.01 to 100, preferably from 0.1 to 20, more preferably from 0.3 to 20.

We supposed that the doping of the proper amount of the metal ions will cause the coordination of the thiophene ring of the polythiophene to the metal ion or the electrostatic interaction between the polythiophene and metal ion, make the polymer backbone more planar, and facilitate approach of the polymer chains each other, to take advantage of forming the polythiophene aggregate with the metal ions.

The optically active polythiophene doped with metal ions according to the present invention shows a CD absorption different from the one not doped with metal ions (cf. FIGS. 2 to 11). The reason why such difference is produced is not sufficiently clear at this stage but it is presumed that the doping with metal ions might afford an influence on the helicity of the main chain (i.e., the chain consisting of the thiophene rings) and the packing in the doped polythiophene aggregate.

According to a conventional technique, it is required for changing the CD spectra of polymers to modify at least either one of the main chain and the side chain in such polymers. Advantageously, the doping with metal ions according to the present invention can change the CD spectrum of the polythiophene aggregate by a simple procedure within a very short time such as 30 seconds.

The polythiophene not doped with metal ions exhibits absorption in UV-vis region. Doping of the polythiophene aggregate with metal ions results in shifting absorption bands, changing absorption coefficient or producing new bands in not only UV-vis region but near IR region (cf. FIG. 1).

As known in the related art field, doping of metal ions affords an influence on the electric conductivity as well as the transition state of the electron. In the spectrum of the polythiophene aggregate doped with Fe(II). (shown in FIG. 1), for example, the novel bands around 800 nm and in near IR region correspond to polaron states. The conductivity of the polythiophene aggregate doped with metal ions can thus change with the type or amount of the metal ions as doped.

The polythiophene aggregate doped with metal ions according to the invention shows good solubility in organic solvents and facilitates the formation of a thin film therewith. The formation can be accomplished by a per se conventional procedure, for example, by applying a solution of the doped polythiophene aggregate in an appropriate organic solvent onto a substrate and evaporating the organic solvent. The thickness of the thin film as formed may be usually from 5 to 5,000 nm, preferably from 10 to 1,000 nm.

Still, the present invention provides a method of changing the CD absorption of a polythiophene of the formula I which comprise doping the polythiophene with metal ions. The substituent R which is present on the thiophene ring of the polythiophene is not required to have a site which can coordinate with metal ions or can exhibit coulomb interaction with metal ions.

The method of the invention may be applied to production of the memory, switch, sensor, etc. by utilization of the doping of metal ions. For example, the poly((S)-(2-methylbutyl)thiophene) aggregate doped with Fe(II) is utilizable for the memory having a good contrast/noise ratio as the g_{obs} factor is increased remarkably and the degree of the change of the optical rotation is significantly large.

Stillmore, the present invention provides a circular dichroism regulator for the polythiophene of the formula I, which comprises metal ions. As the source of the metal ions, there may be used metal salts as hereinabove stated. For enhancement of the CD absorption of poly{3-(S)(2-methylbutyl)thiophene}, the use of Fe(II) is desirable so that the 59% increase in g_{obs} factor can be observed. For decrease of the CD absorption of poly(3-(S)-(2-methylbutyl)thiophene), Cu(I), Cu(I) and Fe(III) may be used so that the decrease of 71-81% in g_{obs} factor is produced.

The invention will now be illustrated but not limited by the following Examples.

Molecular weight of poly{3-(S)-2-methylbutyl-thiophene} were estimated by size exclusion chromatography (SEC) on a Shodex KF806M column (eluent THF, 30° C.) using a Shimadzu liquid chromatograph equipped with a photodiode array detector and calibrated using polystyrene standards.

NMR spectra were recorded on a Varian Unity 300 spectrometer relative to tetramethylsilane as internal standard in CDCl₃ at 30° C.

CD and simultaneous UV-Vis spectra were recorded using a JASCO J-725 spectropolarimeter (1 mm path length cell; sample concentration=1.0×10⁻⁴ mol/L of the thiophene repeating unit)

### EXAMPLE 1

### Preparation of poly(3-(S)-2-methylbutylthiophene) (PMBT)

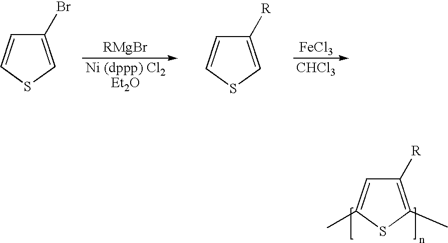

Preparation of 3-(S)-2-methylbutylthiophene (MBT)

(S)-2-Methylbutyl magnesium bromide [prepared from (S)-2-methylbutyl bromide (0.12 mol)] in diethyl ether (150 ml) were added to ethyl ether solution (100 ml) of 3-bromothiophene (16.3 g, 0.10 mol) in the presence of Ni(dppp)Cl₂ ([1,2-bis(diphenylphosphino)propane]dichloro-nickel(II)) at room temperature. The mixture was stirred for 4 h, and then gently refluxed for 8 h. 1.0M Hydrochloric aqueous solution (100 ml) was added, and water layer was extracted using ethyl ether (2×50 ml). The organic layer was combined, washed with water (3×100 ml) and dried over magnesium sulfate. The product was purified by vacuum distillation. ¹³C NMR(CDCl₃, 75.43 MHz) δ 11.51, 19.12, 29.20, 36.03, 37.53, 120.68, 124.83, 128.76, 141.88.

bp: 78-82° C./8 mmHg; yield 58%; [α]_{D}²⁴=7.37 (neat).

Preparation of poly(3-(S)-2-methylbutylthiophene) (PMBT)

MBT (1.5 g, 10 mmol) in anhydrous chloroform (10 ml) was added dropwise slowly to the mixture of ferric chloride (40 mmol) and chloroform (90 ml), with vigorously stirred overnight under argon atmosphere at room temperature. The reaction mixture was poured-into 1 L methanol, and the solid formed was collected by filtration. This oxidized product was dissolved in chloroform (200 ml) and washed with 10% hydrazine aqueous solution (3×100 ml). The chloroform layer was separated and dried over CaCl₂. After the solvent was removed, PMBT which had no metal, was obtained.

M_{w}=93,600; Mₙ=35,260.

¹³C NMR(CDCl₃, 75.43 MHz): δ 11.50, 19.24, 29.49, 35.97, 36.50, 120.60, 121.09, 133.58, 138.92.

### EXAMPLE 2

### Preparation of Poly(3-(S)-2-methyl-butylthiophene) Aggregate with Fe(II)

Process A) 1×10⁻³ M PMBT solution in chloroform (0.5 ml) was placed in a 10 ml sample bottle. Under magnetic stirring (500 rpm), 5×10⁻³ M iron(II) perchlorate solution in acetonitrile (0.1 ml) was added quickly. 30 seconds later, n-octanol (4.4 ml) was added quickly. After stirring for 30 seconds, the CD and TV-vis spectra were measured (FIG. 1, FIG. 2).

Process B) 1×10⁻³ M PMBT solution in chloroform (0.5 ml) was placed ill a 10 ml sample bottle. Under magnetic stirring (500 rpm), n-octanol (4.4 ml) was added quickly. The mixture was stirred. 30 seconds later, 5×10⁻³ M iron(II) perchlorate solution in acetonitrile (0.1 ml) was added quickly. After stirring for 30 seconds, the CD and UV-vis spectra were measured (FIG. 3).

The aggregates obtained by Process A and B, were collected on the microfilter with the pore size of 0.1 μm, washed with hexane and dried under vacuum.

### EXAMPLE 3

Other PMBT aggregates with metals were prepared according to Process A and B of Example 2, except that in place of iron(II) perchlorate, Li(SO₃CF₃), Na(SO₃CF₃), K(SO₃CF₃), Ag(SO₃CF₃), Ag(ClO₄), Zn(SO₃CF₃)₂, Eu(SO₃CF₃)₃, Cu(SO₃CF₃), Cu(SO₃CF₃)₂ and Fe(ClO₄)₃ were used to obtain the PMBT aggregates in which Li, Na K⁺, Ag⁺, Zn²⁺, Cu⁺ Cu²⁺ and Fe³⁺ were doped respectively, and the CD and UV-vis spectra were measured (FIG. 4-FIG. 11).

Each aggregate obtained by Process A and B, was collected on the microfilter with the pore size of 0.1 μm, washed with hexane and dried under vacuum.

TABLE 1

| | Process A | | | Process B | | |
|---|---|---|---|---|---|---|
| | g_{obs} | | | g_{obs} | | |
| | (position in the | | λₘₐₓ | (position in the | | λₘₐₓ |
| | CD spectra, nm) | | in the UV- | CD spectra, nm) | | in the UV- |
| | Positive | Negative | vis spectra | Positive | Negative | vis spectra |
| Metal Ions | (×10⁻⁴) | (×10⁻⁴) | (nm) | (×10⁻⁴) | (×10⁻⁴) | (nm) |
| none | 6.9(462) | −1.5(555) | 503 | 6.8(467) | −1.6(558) | 475 |
| LiSO₃CF₃ | 6.3(462) | −1.3(559) | 484 | 6.7(462) | −1.6(558) | 475 |
| NaSO₃CF₃ | 5.5(463) | −1.1(561) | 488 | 6.2(462) | −1.5(555) | 475 |
| KSO₃CF₃ | 6.5(458) | −1.3(559) | 491 | 6.2(468) | −1.7(561) | 475 |
| AgSO₃CF₃ | 7.5(462) | −1.6(555) | 478 | 8.7(460) | −2.2(555) | 475 |
| AgCIO₄ | 5.1(467) | −1.1(561) | 478 | 7.9(462) | −2.1(555) | 475 |
| Zn(SO₃CF₃)₂ | 7.9(465) | −1.7(555) | 478 | 7.4(465) | −1.9(555) | 475 |
| Eu(SO₃CF₃)₃ | 8.6(462) | −1.9(555) | 478 | 7.0(462) | −1.9(555) | 475 |
| CuSO₃CF₃ | 2.0(483) | −0.35(615) | 558 | 6.4(469) | −1.6(561) | 475 |
| Cu(SO₃CF₃)₂ | 1.4(500) | −0.17(615) | 550 | 7.6(464) | −2.1(555) | 475 |
| Fe(CIO₄)₃ | 1.3(520) | −0.20(588) | 527 | 7.7(462) | −1.9(555) | 475 |
| Fe(CIO₄)₂ | 11(477) | −2.2(570) | 515 | 5.9(465) | −1.5(555) | 478 |

chiral anisotropy factor; g_{obs}=Δε/ε

As shown in the table 1, g_{oba} factors in the CD spectra and λₘₐₓ values in the UV-vis spectra of the PMBT aggregates with metals varied from that of the PMBT aggregate with no metal (shown as “none” in table 1), and the degree of these variances depended on the type of metals. For the PMBT aggregate with Fe(II) prepared according to Process A, g_{obs} factor at positive peak in the CD spectrum was remarkably increased (59%). This means that the doping with Fe(II) led remarkable increase of optical activity of the aggregates. Whereas for the PMBT aggregates with Cu(I), Cu(II) and Fe(III) prepared according to Process A, the g_{obs} factors at positive peaks in the CD spectra were dramatically decreased (71-81%).

### BRIEF DESCRIPTION OF DRAWINGS

FIG. 1: UV-vis-neat IR spectrum of poly{3-(S)-(2-methylbutyl)thiophene} aggregate with Fe(II) prepared by process A.

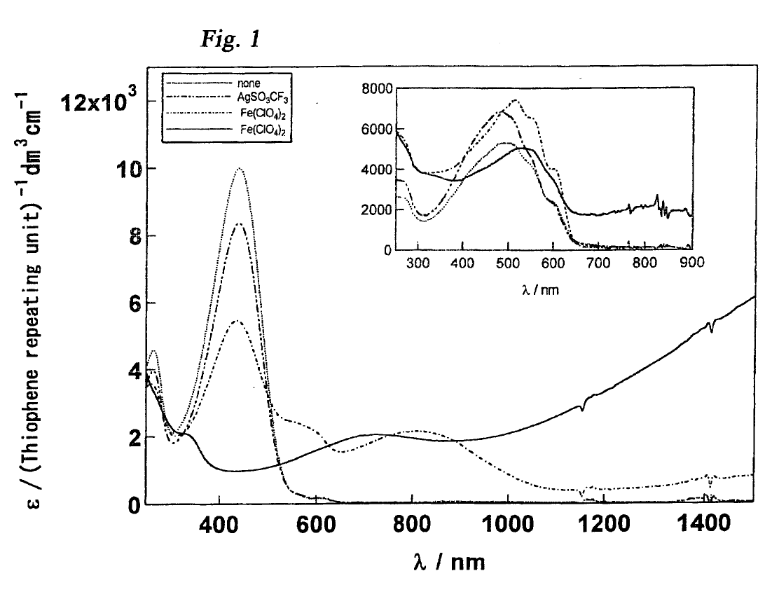

FIG. 2: CD spectrum (upper) and UV-vis spectrum (lower) of poly{3-(S)-(2-methylbutyl)thiophene} aggregate with Fe(II) prepared by process A.

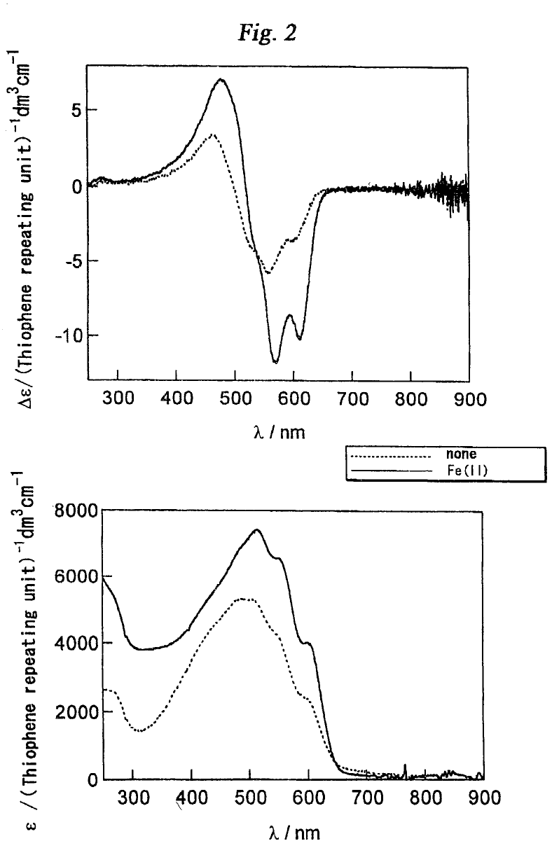

FIG. 3: CD spectrum (upper) and UV-vis spectrum (lower) of poly{3-(S)-(2-methylbutyl)thiophene} aggregate with Fe(II) prepared by process B.

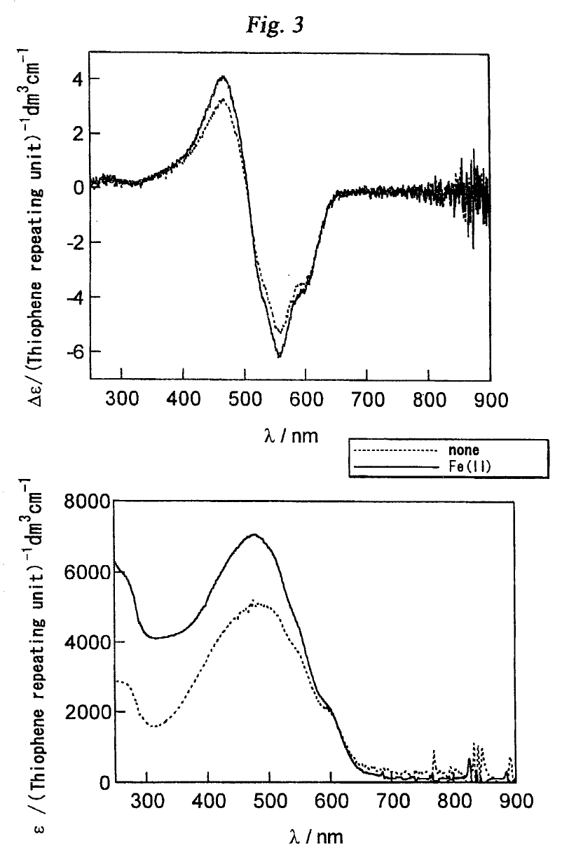

FIG. 4: CD spectra (upper) and UV-vis spectra (lower) of poly{3-(S)-(2-methylbutyl)thiophene} aggregate with Li(I), Na(I) and K(I) prepared by process A.

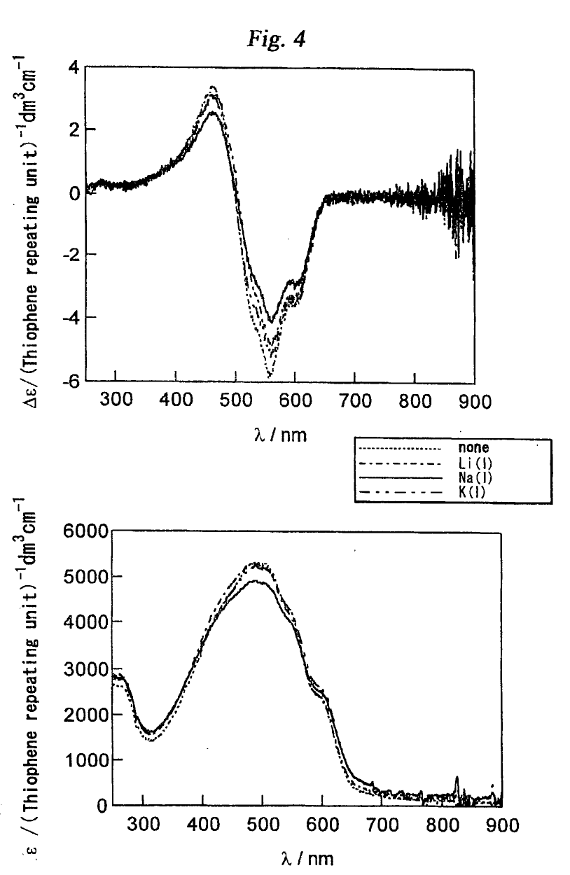

FIG. 5: CD spectra (upper) and UV-vis spectra (lower) of poly{3-(S)-(2-methylbutyl)thiophene} aggregate with Li(I), Na(I) and K(I) prepared by process B.

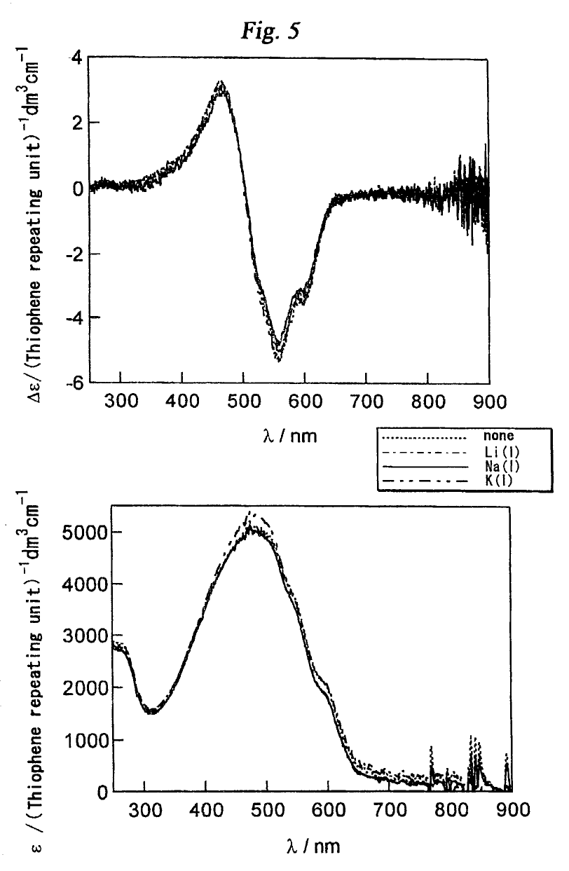

FIG. 6: CD spectra (upper) and UV-vis spectra (lower) of poly{3-(S)-(2-methylbutyl)thiophene} aggregate with Cu(I), Cu(II) and Fe(III) prepared by process A.

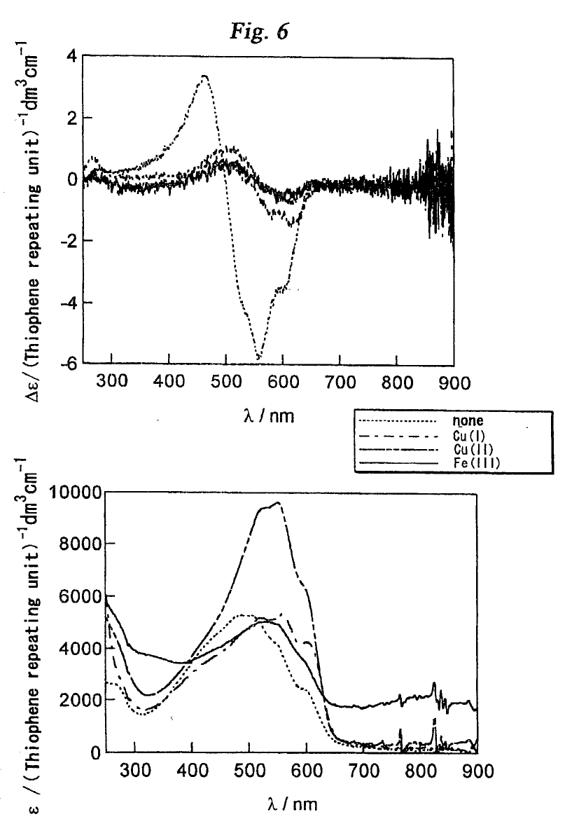

FIG. 7: CD spectra (upper) and UV-vis spectra (lower) of poly{3-(S)-(2-methylbutyl)thiophene} aggregate with Cu(I), Cu(II) and Fe(III) prepared by process B.

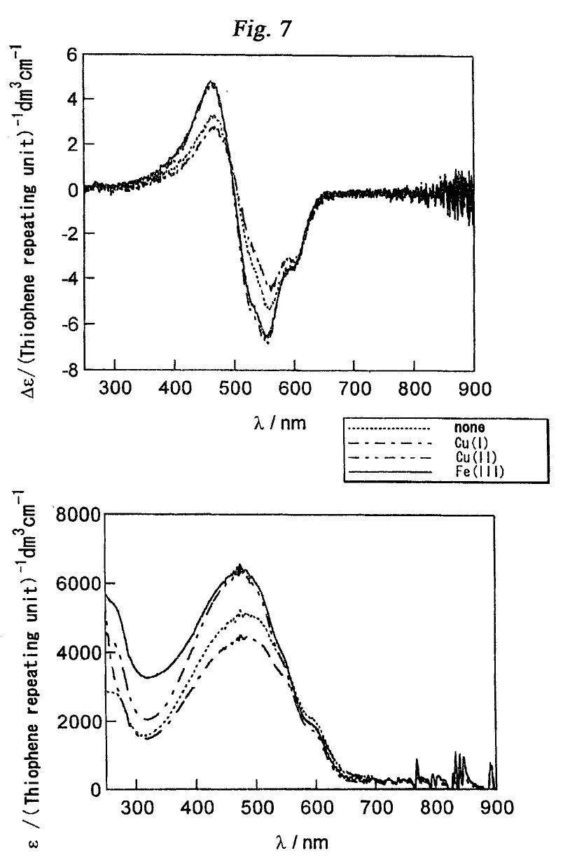

FIG. 8: CD spectra (upper) and V-vis spectra (lower) of poly{3-(S)-(2-methylbutyl)thiophene} aggregate with Eu(III) and Zn(II) prepared by process A.

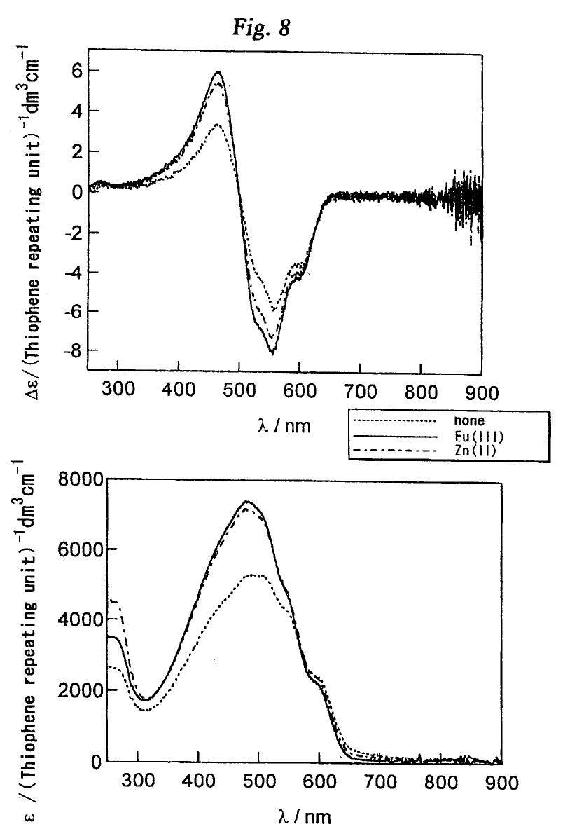

FIG. 9: CD spectra (upper) and UV-vis spectra (lower) of poly{3-(S)-(2-methylbutyl)thiophene} aggregate with Eu(III) and Zn(II) prepared by process B.

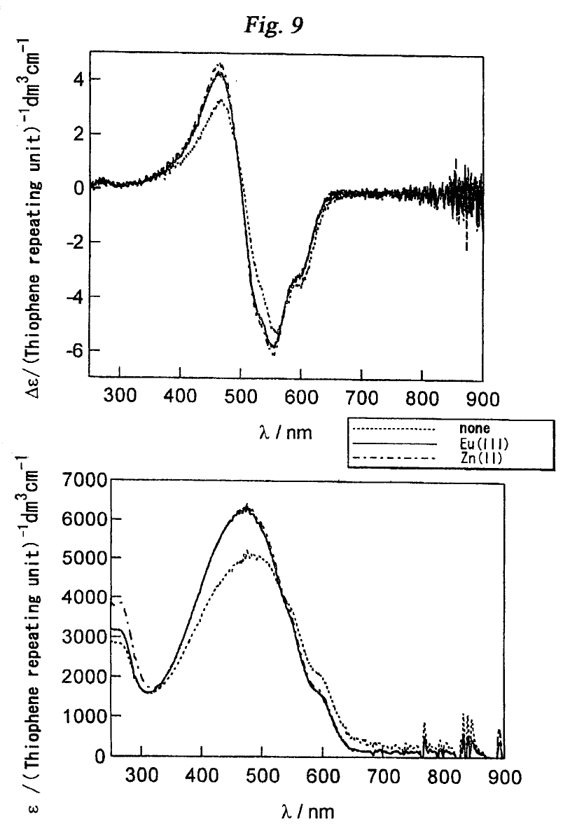

FIG. 10: CD spectra (upper) and UV-vis spectra (lower) of poly{3-(S)-(2-methylbutyl)thiophene} aggregate with Ag(I) prepared by process A using Ag(ClO₄) or Ag(SO₃CF₃).

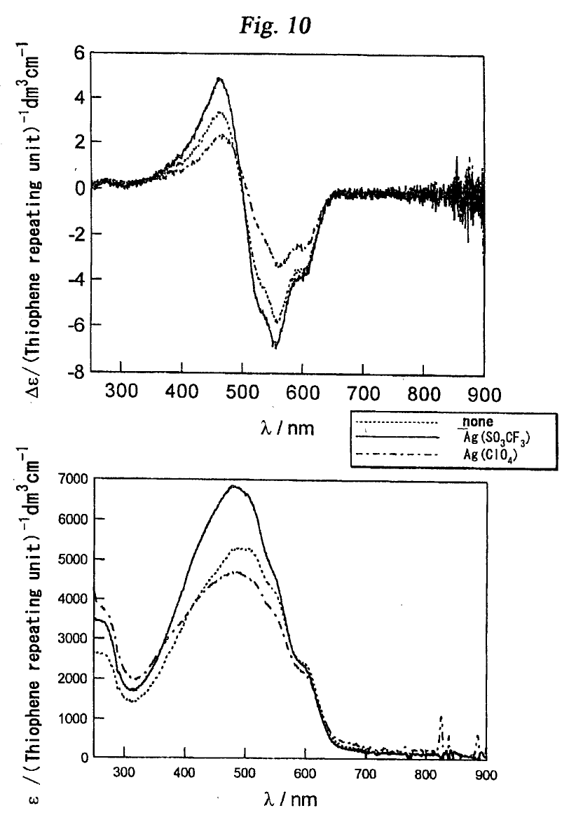

FIG. 11: CD spectra (upper) and UV-vis spectra (lower) of poly{3-(S)-(2-methylbutyl)thiophene} aggregate with Cu(I), Cu(I) and Fe(III) prepared by process B using Ag(ClO₄) or Ag(SO₃CF₃).

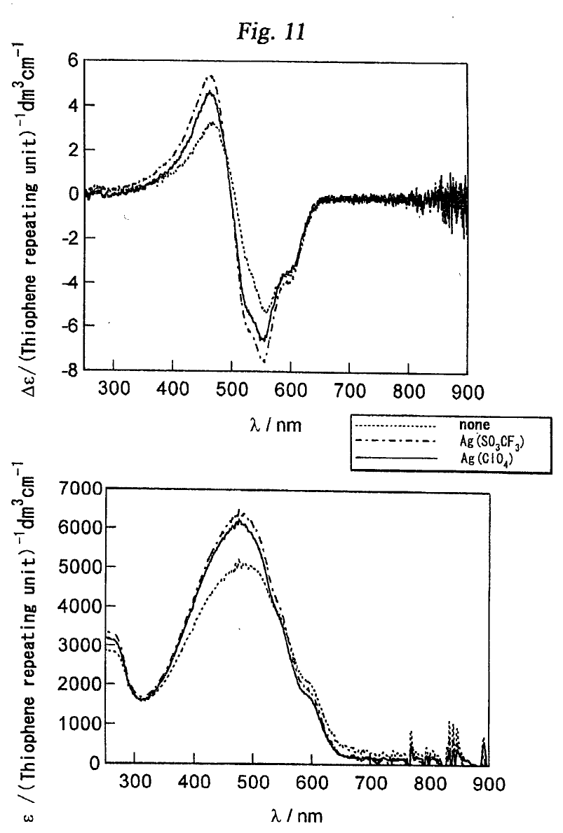

1. A polythiophene aggeregate doped with metal ions, said polythiophene being representable by the formula: 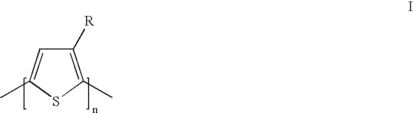
wherein R is an optically active group and n is 10 to 10,000.

2. The polythiophene aggregate according to claim 1, wherein the optically active group is an alkyl or alkenyl group having 5 to 20 carbon atoms.

3. The polythiophene aggregate according to claim 2, wherein the alkyl or alkenyl group is (S) or (R)-2-methylbutyl, (S) or (R)-3-methylpentyl, (S) or (R)-3,7-dimethyloctyl or (S) or (R)-citronellyl.

4. A process for preparing the polythiophene aggregate according to any of claims 1 to 3, which comprise dissolving the polythiophene into a good solvent, adding a metal salt to the resultant solution and adding a poor solvent thereto.

5. A process for preparing the polythiophene aggregate according to any of claims 1 to 3, which comprises dissolving the polythiophene into a good solvent, adding a poor solvent to the resultant solution and adding a metal salt thereto.

6. A method of changing the circular dichroism absorption of a polythiophene of the formula I, which comprise doping the polythiophene with metal ions.

7. A circular dichroism regulator of a polythiophene of the formula I, which comprises metal ions.
